(19) United States
(12) Patent Application Publication
(10) Pub. No.: US 2026/0260046 A1
(43) Pub. Date: Sep. 3, 2026

(54) CONTAINER GEOMETRY IDENTIFIER USING GRAIN PILING SIMULATOR

(71) Applicant: Deere & Company, Moline, IL (US)

(72) Inventors: Mason K. DREES, West Des Moines, IA (US); Kellen E. O'CONNOR, Des Moines, IA (US)

(21) Appl. No.: 19/067,113

(22) Filed: Feb. 28, 2025

(51) Int. Cl. G06F 30/28

(52) U.S. Cl. CPC G06F 30/28

(57) ABSTRACT

An unloading vehicle performs an unloading operation, unloading material into a container. A perception sensor generates unloading data indicative of fill characteristics of the unloading operation. A simulator performs a separate simulation to generate simulated fill characteristics corresponding to the unloading operation for each of a plurality of different container geometries. An error generation system compares the simulated characteristics estimated by the simulator, for each of the plurality of different container geometries, to the fill characteristics indicated by the perception sensor to generate an error value corresponding to each of the plurality of different container geometries. A container geometry, of the plurality of different container geometries, that has the lowest corresponding error value is selected as the container geometry to be used by the simulator to estimate fill characteristics corresponding to subsequent unloading operations.

### FIELD OF THE DESCRIPTION

The present description generally relates to machines that load material into receiving vehicles or other containers. More specifically, the present description relates to automatic identification of a geometry of a receiving vehicle or other container using a grain piling simulator.

### BACKGROUND

There are a wide variety of different types of vehicles that load material into other vehicles or other containers. Some such vehicles include agricultural vehicles such as forage harvesters or other harvesters (such as combine harvesters, sugarcane harvesters, silage harvesters, etc.), that harvest grain or other crops. Such harvesters often unload material into carts, which may be pulled by tractors, or semitrailers, as the harvesters are moving. Other vehicles perform unloading into a stationary vehicle, such as when a tractor-pulled grain cart unloads material into a haulage vehicle, such as a semi-truck. Other vehicles that unload material into receiving vehicles include construction vehicles, such as cold planers that unload into a dump truck, and other vehicles.

Taking an agricultural harvester as an example of an unloading vehicle, while harvesting in a field using a forage harvester or combine harvester, an operator attempts to control the harvester to maintain harvesting efficiency, during many different types of conditions. The soil conditions, crop conditions, etc. can all change. This may result in the operator changing control settings. This means the operator needs to devote a relatively large amount of attention to controlling the forage harvester or combine harvester.

At the same time, a semitruck or tractor-pulled cart (a receiving vehicle), is often in position relative to the harvester (e.g., alongside the harvester or behind the harvester) so that the harvester can fill the semitrailer or cart, while moving through the field. In some current systems, this requires the operator of the harvester to control the position of the unloading spout and flap so that the truck or cart is filled evenly, but not over filled. Even a momentary misalignment between the spout and the truck or cart may result in hundreds of pounds of harvested material being dumped on the ground, rather than in the truck or cart.

Further, there may be multiple different unloading operations that occur during a harvesting operation. For instance, taking a combine harvester as an example, the combine harvester may unload harvested material into a material transfer vehicle, such as a tractor-pulled grain cart. Once the material transfer vehicle is filled to a desired fill level, the material transfer vehicle navigates toward a container such as a haulage vehicle (e.g., a semi-trailer), pulls alongside the container, and transfers the harvested material to the container. As the material transfer vehicle approaches the container, a control system or operator positions an unloading spout or auger, and then, once alongside the container, engages the unloading auger on the material transfer vehicle to unload the harvested material from the material transfer vehicle into the container.

The discussion above is merely provided for general background information and is not intended to be used as an aid in determining the scope of the claimed subject matter.

### SUMMARY

An unloading vehicle performs an unloading operation, unloading material into a container. A perception sensor generates unloading data indicative of fill characteristics of the unloading operation. A simulator performs a separate simulation to generate simulated fill characteristics corresponding to the unloading operation for each of a plurality of different container geometries. An error generation system compares the simulated characteristics estimated by the simulator, for each of the plurality of different container geometries, to the fill characteristics indicated by the perception sensor to generate an error value corresponding to each of the plurality of different container geometries. A container geometry, of the plurality of different container geometries, that has the lowest corresponding error value is selected as the container geometry to be used by the simulator to estimate fill characteristics corresponding to subsequent unloading operations.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

FIG. 1 is a partial pictorial, partial block diagram of one example of an unloading system.

FIG. 2 is a partial pictorial, partial block diagram of one example of an unloading system.

FIG. 3 is a partial pictorial, partial block diagram of one example of an unloading system.

FIG. 4 is a partial pictorial, partial block diagram of one example of an unloading system.

FIG. 5 is a partial pictorial, partial block diagram of one example of an unloading system.

FIG. 6 is a pictorial illustration showing one example of an operator interface device in displaying a fill level of material in a container.

FIG. 7 is a block diagram showing one example of a fill control system.

FIGS. 8A and 8B (collectively referred to herein as FIG. 8) illustrate a flow diagram showing one example of the operation of the fill control system in identifying a container geometry.

FIG. 9 is a block diagram showing one example of the system shown in other FIGs. deployed in a remote server environment.

FIGS. 10, 11, and 12 show examples of mobile devices that can be used in the architectures and systems shown in other FIGs.

FIG. 13 is a block diagram showing one example of a computing environment that can be used in the systems and architectures shown in other FIGs.

### DETAILED DESCRIPTION

For the purposes of promoting an understanding of the principles of the present disclosure, reference will now be made to the examples illustrated in the drawings, and specific language will be used to describe the same. It will nevertheless be understood that no limitation of the scope of the disclosure is intended. Any alterations and further modifications to the described devices, systems, methods, and any further application of the principles of the present disclosure are fully contemplated as would normally occur to one skilled in the art to which the disclosure relates. In particular, it is fully contemplated that the features, components, and/or steps described with respect to one example may be combined with the features, components, and/or steps described with respect to other examples of the present disclosure.

The present discussion proceeds with respect to an unloading vehicle being an agricultural harvester, but it will be appreciated that the present discussion is also applicable to construction machines, material transfer vehicles, or other material unloading vehicles that unload material into a receiving vehicle or other container. As discussed above, it can be very difficult for an operator to maintain high efficiency in controlling a harvester or other unloading vehicle, and to optimally monitor the position of the receiving vehicle or container during an unloading operation. This difficulty can even be exacerbated when the receiving vehicle is located behind the harvester (such as a forage harvester), so that the harvester is executing a rear unloading operation, but the difficulty also exists in side-by-side unloading scenarios.

Further, it can be difficult for the operator of the material transfer vehicle to observe the fill level of material in a haulage vehicle, such as a semi-trailer or other container and to move the material transfer vehicle along the semi-trailer or other container to achieve an even fill level across the semi-trailer or other container. The operator of the material transfer vehicle must position the material transfer vehicle accurately to not only achieve a uniform fill level but avoid undesirable contact between the material transfer vehicle and the semi-trailer or other container.

To address these issues, some automatic fill control systems have been developed to automate portions of the unloading process. One such automatic fill control system uses a stereo camera on the harvester or other unloading vehicle to capture an image of the receiving vehicle or other container. An image processing system detects point cloud data, from which material height within the receiving vehicle or container can be obtained. In one example, the automatic fill control system divides the opening of the receiving vehicle or other container into a two-dimensional grid of cells. The material height can be used to automatically aim the spout toward cells that have more empty spots and control the flap position (and thus material trajectory) to achieve a more even fill, while reducing spillage. Such systems can control the unloading vehicle to fill the receiving vehicle or other container according to a fill strategy (such as front-to-back, back-to-front, etc.) that is set by the operator or that is set in other ways.

In addition, some current unloading vehicles are provided with a machine synchronization control system. The unloading vehicle may, for instance, be a combine harvester so that the spout is not movable relative to the frame during normal unloading operations. Instead, the relative position of the receiving vehicle and the combine harvester is changed to fill the receiving vehicle as desired. Thus, in a front-to-back fill strategy, for instance, the relative position of the receiving vehicle, relative to the combine harvester, is changed so that the spout is first filling the cells or grid locations in the two dimensional grid corresponding to the receiving vehicle at the front end, and then gradually fills the cells of the grid corresponding to the receiving vehicle moving rearward.

In such an example, the combine harvester and receiving vehicle may have machine synchronization systems which communicate with one another. When the relative position of the two vehicles is to change (e.g., when the combine harvester should be loading material into a location defined by a different cell or grid location), the machine synchronization system on the combine harvester can send a message to the machine synchronization system on the receiving vehicle to “nudge” the receiving vehicle slightly forward or rearward relative to the combine harvester, as desired. By way of example, the machine synchronization system on the combine harvester may receive a signal from the fill control system on the combine harvester indicating that the fill height of material at the location of the receiving vehicle that is currently being filled is approaching its desired fill level. In that case, the machine synchronization system on the combine harvester can send a “nudge” signal to the machine synchronization system on the receiving vehicle (e.g., to a tractor of a tractor-pulled the grain cart). The “nudge”, once received by the machine synchronization system on the receiving vehicle, causes the receiving vehicle to automatically momentarily speed up or slow down, thus nudging the position of the receiving vehicle forward or rearward, respectively, relative to the combine harvester. By automatically it is meant, for example, that the operation is performed without further human involvement except, perhaps, to initiate or authorize the operation.

Similar operation can be achieved when the receiving vehicle is stationary (e.g., when a tractor-pulled grain cart is unloading into a haulage vehicle such as a semi-trailer). In that case, the stereo camera on a spout of the grain cart captures point cloud data corresponding to material being unloaded into the semi-trailer. The automatic fill control system can divide the opening in the semi-trailer into a grid of cells. The height of the material in the semi-trailer in the cell or grid location currently being filled is computed or estimated based upon the point cloud data. When the height of the material reaches a desired fill level, then the unloading vehicle (e.g., the tractor-pulled grain cart) is nudged forward to change the landing point of material (e.g., the cell or grid location being filled) in the semi-trailer.

There are conditions under which the perception sensor (e.g., the stereo camera) may become inaccurate. For instance, when lighting conditions become suboptimal (such as when performing unloading operations at night), or in high dust environments (which can often occur during an unloading operation), then the perception sensor may have difficulty in generating the point cloud data that is used to estimate the fill height of material in the receiving vehicle or other container.

Therefore, some current systems use a fill simulator to simulate the fill height during the unloading operation. Such a fill simulator may take, as inputs, things that may affect the topography or behavior of the grain pile as the grain is unloaded into the receiving vehicle or container during the unloading operation. Such inputs may include things like the grain type, expected kernel size, grain moisture, etc. Further, a fill simulator may take, as an input, the unloading rate at which material is unloaded from the unloading vehicle. In addition, to accurately simulate fill height (or material topography or other fill characteristics) in the receiving vehicle or other container, the fill simulator receives, as an input, a geometry of the interior of the receiving vehicle or container. This can present difficulties. There are a wide variety of different types and shapes of receiving vehicles and containers. However, if the fill simulator does not have knowledge of the geometry of the receiving vehicle, then the fill simulator will likely provide an inaccurate simulation result indicating an inaccurate fill level or outputting other inaccurate fill characteristics. This compromises the accuracy of the automated fill control operation.

The present description thus proceeds with respect to a geometry identification system that automatically identifies the interior geometry of the receiving vehicle or container. A first unloading operation into the receiving vehicle or container is performed when conditions are favorable for using a perception sensor to perceive the fill level. The geometry identification system collects data indicative of fill characteristics corresponding to the first unloading operation. That data can include, for instance, the location at which material was unloaded into the receiving vehicle or container (e.g., the cell or grid location), and time data indicating how long the material was unloaded at that location. The location and time data can be collected for each location at which material was unloaded into the receiving vehicle or container during the first unloading operation. Similarly, an indication can be received from the perception system as to the final topography of the unloaded material in each location and/or the final topography of material in the receiving vehicle or container. Also, an unload rate corresponding to the unloading operation can be sensed or computed. The unload rate is indicative of the rate at which material was unloaded from the unloading vehicle into the receiving vehicle or container.

The geometry identification system then selects, from a data store or elsewhere, a geometry corresponding to a first receiving vehicle or container and in the fill simulator runs a simulation based upon that selected geometry. The fill simulator generates simulated fill characteristics for the selected geometry. The simulated fill characteristics output by the fill simulator for that geometry are compared against the fill characteristics output by the perception system, and an error value is generated for the selected geometry. Then, a different geometry is selected, and the fill simulator runs a simulation based on that geometry. An error value is calculated for that geometry as well. This process is repeated until the simulator has run a simulation for all desired geometries. Then, the error values corresponding to each geometry are compared to identify the geometry with a lowest corresponding error value. The geometry with the lowest corresponding error value is selected as the geometry that the simulator will use for subsequent unloading operations into the receiving vehicle or container.

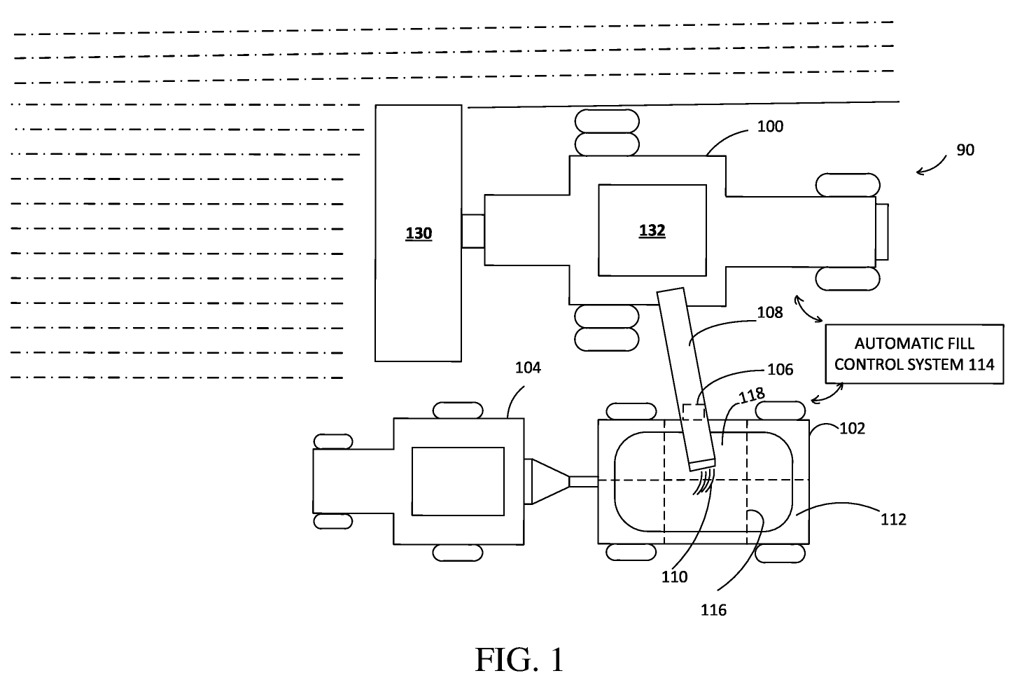

FIG. 1 is a pictorial illustration showing one example of an unloading system 90 with a combine harvester 100 (e.g., a material unloading vehicle also referred to as a leading vehicle) filling a tractor-pulled grain cart (or receiving vehicle) 102. Combine harvester 100 has a header 130 that engages crop. The crop is processed and placed in a clean grain tank 132, where it is unloaded (such as using an auger) through spout 108 into the receiving vehicle or cart 102. Cart 102 thus defines an interior that forms a receiving vessel for receiving harvested material through a receiving area 112 defined by the walls of cart 102. In the example shown in FIG. 1, tractor 104 (a towing vehicle also referred to as a following vehicle), that is pulling grain cart 102, is positioned alongside harvester 100. Also, in the example illustrated in FIG. 1, harvester 100 has a perception sensor such as a stereo camera 106 mounted on the spout 108 through which the harvested material 110 is traveling. The spout 108 can be pivotally or rotatably mounted to a frame of harvester 100. In the example shown in FIG. 1, the perception sensor 106 is a stereo-camera or a mono-camera that captures an image (e.g., a still image or video) of the receiving area 112 of cart 102. It will also be noted, however, that perception sensor 106 could be a RADAR sensor, a LIDAR sensor or another sensor that senses three-dimensional (3D) data.

In the example shown in FIG. 1, unloading system 90 includes an automatic fill control system 114 that includes image processing, as discussed above. It is noted that automatic fill control system 114 can be located on harvester 100, or on the receiving vehicle (e.g., on tractor 104 and/or grain cart 102). Automatic fill control system 114 can also be distributed among different locations (such as partially on harvester 100, partially on the receiving vehicle - tractor 104 and/or grain cart 102, partially at a remote computing system, such as a remote server computing system or cloud system) and/or elsewhere. Automatic fill control system 114 is shown as residing in a single location in FIG. 1 for the sake of example only.

Thus, the automatic fill control system 114 attempts to identify the location of the receiving area 112 by identifying the edges or walls of the receiving area and then uses point cloud data generated by the perception sensor 106 to compute the height of harvested material in grain cart 102, and the location of that material in grain cart 102. In one example, the image processing system in automatic fill control system 114 divides the receiving area 112 into cells represented by the grid of dashed lines 116 displayed over the top of opening 112. Automatic fill control system 114 identifies a particular cell or grid location where unloading is to occur, and generates control signals to position the outlet end of spout 108 so that spout 108 is unloading material into the identified cell or grid location. In the example shown in FIG. 1, spout 108 is unloading material into cell or grid location 118. The system can thus automatically control the position of spout 108 to direct the trajectory of material 110 into the desired cell of receiving area 112 of grain cart 102 to obtain an even fill (or another desired fill) throughout the entire length and width of grain cart 102, while not overfilling grain cart 102. By automatically, it is meant, for example, that the operation is performed without further human involvement except, perhaps, to initiate or authorize the operation.

In one example, automatic fill control system 114 processes an image captured by perception sensor 106 to identify a fill height of material in the cell currently being loaded. However, as discussed above, it may be that conditions are not optimal for identifying the fill height of material based upon outputs from perception sensor 106. For instance, the unloading operation may be performed at night, or in other lowlight conditions, or there may be heavy dust in the environment of perception sensor 106.

Therefore, in some examples, automatic fill control system 114 receives the geometry of grain cart 102 and the unloading rate of harvester 100 and uses a simulator to simulate the height or topography of material in each of the cells or grid locations defined by grid 116. Then, when the simulated fill height or fill level in a particular cell or grid location reaches a desired level, automatic fill control system 114 can generate control signals to change the position of the outlet end of spout 108 so that it is filling material into a different cell or grid location in grid 116. This can continue until the simulated fill height or topography of material in each of the cells or grid locations reaches a desired level.

However, to perform such a simulation, the simulator receives, as an input, the geometry of grain cart 102. This can be difficult, because there are a wide variety of different types of grain carts 102 that have different geometries, so the range of possible geometries is relatively wide. Similarly, it may be that material is being loaded into a different container, such as a semi-trailer, in which case the range of possible geometries is wider still.

Thus, in accordance with one example, automatic fill control system 114 includes a geometry identification system (shown and described in greater detail in later FIGs.) that automatically identifies the geometry of grain cart 102 (or other container). A first unloading operation is performed, where conditions are favorable for performing automatic fill control based upon the output from perception sensor 106, and perception sensor 106 thus senses fill characteristic values corresponding to the first unloading operation (such fill characteristics can include things such as fill height, overall topography, etc.). For example, automatic fill control system 114 saves the amount of time that the outlet end of spout 108 is positioned over each cell or grid location in grid 116, as well as the unloading rate of material from harvester 100. Then, automatic fill control system 114 selects a predefined geometry (e.g., from a library of geometries or elsewhere) and performs a simulation. The simulator generates simulated values for the same fill characteristics generated based upon the output of perception sensor 106. Automatic fill control system 114 iterates through a plurality of different geometries and calculates an error value corresponding to each geometry based upon the difference between the simulated fill characteristic values generated by the simulator and the fill characteristic values generated based upon the output of perception sensor 106. The geometry corresponding to the lowest error value is identified as the geometry of grain cart 102. Therefore, in subsequent unloading operations, automatic fill control system 114 uses the identified geometry to perform automated fill control based upon the output of the simulator instead of based on the output from perception sensor 106.

For example, when executing a back-to-front automatic fill strategy, the automatic fill control system 114 may attempt to move the spout and flap or a machine synchronization system can position the vehicles relative to one another, so the material begins landing at a first cell or grid location in the back of grain cart 102. Then, once a desired fill level is reached at that cell or grid location in the back of grain cart 102, the automatic fill control system moves the spout and flap, or the machine synchronization system nudges the receiving vehicle to change the position of the vehicles relative to one another, so the material begins landing at a cell or grid location just forward of the first cell or grid location that was filled in grain cart 102. This continues until grain cart 102 is filled or until the unloading vehicle stops unloading material.

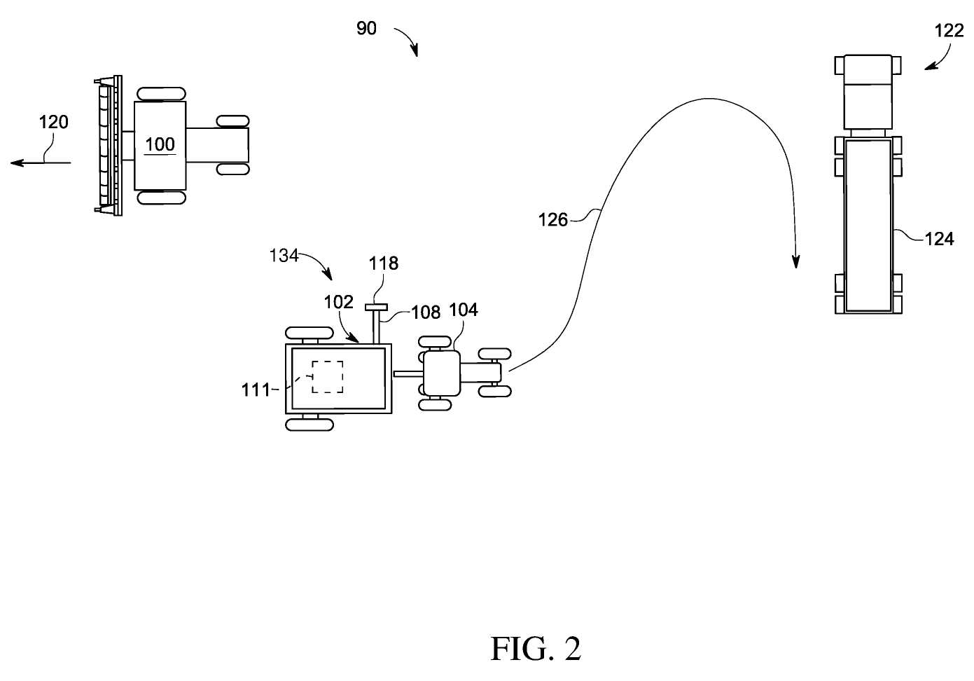

FIG. 2 is a pictorial illustration of one example of an unloading system 90. Some items are similar to those shown in unloading system 90 in FIG. 1, and those items are similarly numbered. In FIG. 2, harvester 100 is moving through a field in a direction indicated by arrow 120. A material transfer vehicle 134 includes a propulsion vehicle (e.g., a tractor) 104 and a grain cart 102. Grain cart 102 is shown having a spout 108 that is used to unload harvested material from grain cart 102. Spout 108 may include a conveyor (such as an auger) that conveys material from grain cart 102 through a housing and out an exit end of spout 108. A flap 118 may be disposed on the exit end of spout 108 to direct material as the material exits through the exit end of spout 108. FIG. 2 also shows that grain cart 102 has a gate 111 disposed at the bottom of grain cart 102. To facilitate the transfer of material out of grain cart 102, gate 111 is opened to a desired position which allows the grain to fall into a hopper or in another collection basin where the grain can be transferred by spout 108.

In the example shown in FIG. 2, grain cart 102 has been filled with harvested material from harvester 100 and is traveling along a travel path indicated by arrow 126 toward a container (e.g., in the example shown in FIG. 2 the container is a semi-truck) 122. To unload material from grain cart 102, an operator (a human operator, an autonomous operator, or a semi-autonomous operator) actuates an actuator to position spout 108 to a deployed position. Tractor 104 pulls the grain cart 102 alongside semi-trailer 124 so that the spout 108 can be engaged to transfer material from grain cart 102 into semi-trailer 124. In one example, spout 108 and/or flap 118 are movable to change the direction of material exiting spout 108 and to thus change the landing point of material inside semi-trailer 124. Also, in one example, spout 108 is driven by a power take off on tractor 104, although it may be driven by other actuators as well. The speed of the power takeoff or other actuator can be controlled to change the landing point as well.

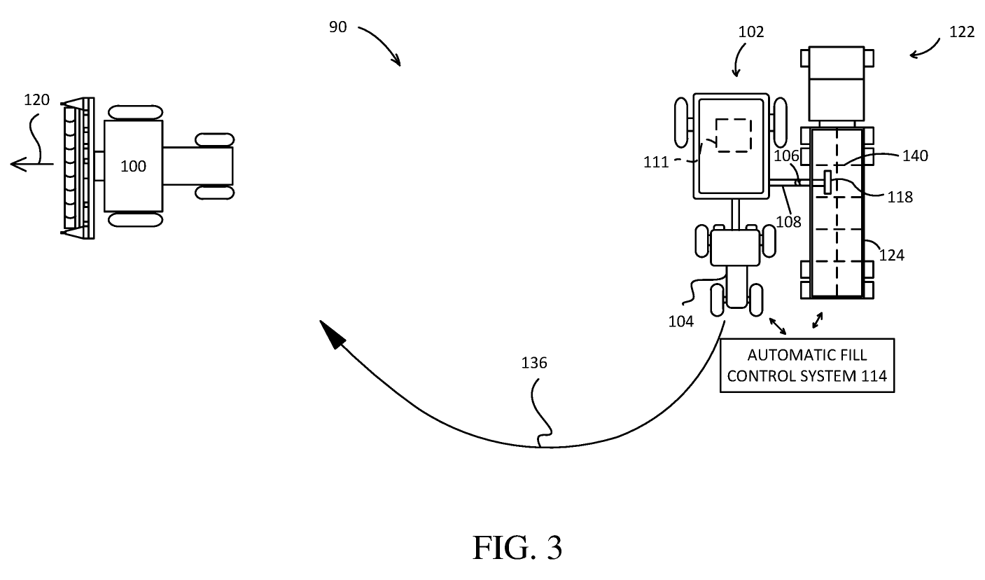

FIG. 3 is a partial pictorial, partial block diagram of agricultural system 90. Some items in FIG. 3 are similar to those shown in FIG. 2 and are similarly numbered. However, FIG. 3 shows that the material transfer vehicle (tractor 104 and grain cart 102) has now pulled alongside haulage vehicle 122 so that the exit end 118 of spout 108 is positioned over semi-trailer 124. Thus, tractor 104 can be controlled to move along semi-trailer 124 as material is unloaded from grain cart 102 into semi-trailer 124.

In the example shown in FIG. 3, automatic fill control system 114 uses image processing to process images captured by perception sensor 106. Automatic fill control system 114 divides the opening of semi-trailer 124 into a grid of cells illustrated by dashed lines 140. When conditions are favorable to perform automatic fill control based upon outputs from perception sensor 106, automatic fill control system 114 can process images captured by perception sensor 106 to compute the fill level of material at a current landing point of material in semi-trailer 124 (e.g., at a particular grid location or cell location where spout 108 is transferring material to semi-trailer 124), to compute other fill characteristics, such as overall topology, the amount of time that spout 108 was positioned over each individual cell or grid location in grid 140, and/or other fill characteristics. Automatic fill control system 114 can use such fill characteristics to control tractor 104 and actuators that may move spout 108 and/or flap 118 to fill the different cells or grid locations in grid 140 to a desired fill level.

Once the unloading operation is complete (e.g., when grain cart 102 is empty, or semi-trailer 124 is full), then the material transfer vehicle can continue along the route indicated by arrow 136 back to agricultural harvester 100 or to a different agricultural harvester or to a different location.

Once the fill characteristics generated based upon the output from perception sensor 106 have been recorded, automatic fill control system 114 can iterate through a plurality of different possible container geometries to generate simulated fill characteristics for each container geometry and compare the simulated fill characteristics to the fill characteristics generated based upon the output from perception sensor 106. Such a comparison generates an error value corresponding to each geometry. Automatic fill control system 114 can then select the geometry corresponding to the lowest error value and use that geometry to perform automated fill control based on simulated fill characteristics during subsequent unloading operations into semi-trailer 124.

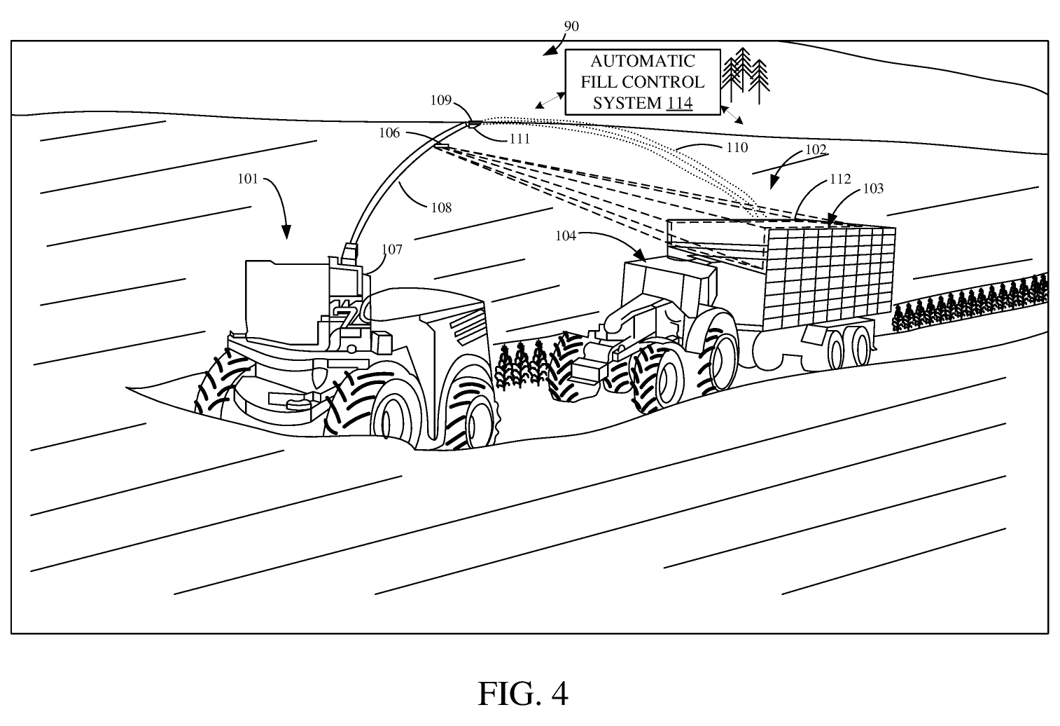

FIG. 4 is a pictorial illustration showing one example of an unloading system 90 in which the unloading vehicle is a self-propelled forage harvester 101 filling tractor-pulled cart 102. Some items are similar to those shown in FIGS. 1-3 above, and they are similarly numbered. In the example shown in FIG. 4, tractor 104, that is pulling cart 102, is positioned directly behind forage harvester 101. Also, in the example illustrated in FIG. 4, forage harvester 101 has perception sensor 106 mounted on the spout 108 through which the harvested material 110 is traveling. The spout 108 can be pivotally or rotatably mounted to a frame 107 of harvester 101. In the example shown in FIG. 4, the perception sensor 106 is a stereo-camera or a mono-camera that captures an image (e.g., a still image or video) of the receiving area 112 of cart 102. It will also be noted, however, that perception sensor 106 could be a RADAR sensor, a LIDAR sensor or another sensor that senses three-dimensional (3D) data. Also, in the example shown in FIG. 4, the receiving area 112 is defined by an upper edge, and corners, of the walls of cart 102.

Further, unloading system 90 includes automatic fill control system 114 that includes image processing, as discussed above. It is noted that automatic fill control system 114 can be located on harvester 101, or on the receiving vehicle (e.g., on tractor 104 and/or cart 102). Automatic fill control system 114 can also be distributed among different locations (such as partially on harvester 101, partially on the receiving vehicle - tractor 104 and/or cart 102, partially at a remote computing system, such as a remote server computing system or cloud system) and/or elsewhere. Automatic fill control system 114 is shown as residing in a single location in FIG. 4 for the sake of example only.

Thus, the automatic fill control system 114 attempts to identify the location of the receiving area 112 by identifying the edges or walls of the receiving area and then uses point cloud data generated by the perception sensor 106 to compute the height of harvested material in cart 102, and the location of that material in cart 102. For instance, the image processing system can divide the opening 112 in cart 102 into a grid of cells or grid locations as shown in previous FIGs. The system can thus automatically control the position of spout 108 and flap 109 to direct the trajectory of material 110 into a desired cell or grid location in the receiving area 112 of cart 102 to obtain an even fill throughout the entire length and width of cart 102, while not overfilling cart 102.

In one example, when conditions are favorable for performing automatic fill control based on images captured by perception sensor 106, automatic fill control system 114 processes images captured by perception sensor 106 to identify fill characteristics corresponding to the unloading operation. Such fill characteristics can include the amount of time that material was loaded into each cell or grid location, the fill level in each cell or grid location, the overall topography of the material in cart 102 and/or in each cell or grid location corresponding to cart 102, among other things. Those fill characteristics can be compared to simulated fill characteristics generated by the simulator in automatic fill control system 114 for each of a plurality of different possible container geometries. The simulated fill characteristics for each container geometry are then compared to the fill characteristics generated using perception sensor 106 to identify an error value corresponding to each geometry. The geometry having the lowest corresponding error value is then selected as the geometry for cart 102 and can be used by the simulator to perform automatic fill control, using the simulator, during subsequent unloading operations into cart 102.

For example, when executing a back-to-front automatic fill strategy, the automatic fill control system 114 may attempt to move the spout and flap or a machine synchronization system can position the vehicles relative to one another, so the material begins landing at a cell or grid location corresponding to a first landing point in the back of cart 102. Then, once a desired fill level is reached at that cell or grid location, the automatic fill control system moves the spout and flap, or the machine synchronization system nudges the receiving vehicle to change the position of the vehicles relative to one another, so the material begins landing at a cell or grid location just forward of the first cell or grid location corresponding to the first landing point in cart 102. This continues until cart 102 is filled or until the unloading vehicle stops unloading material.

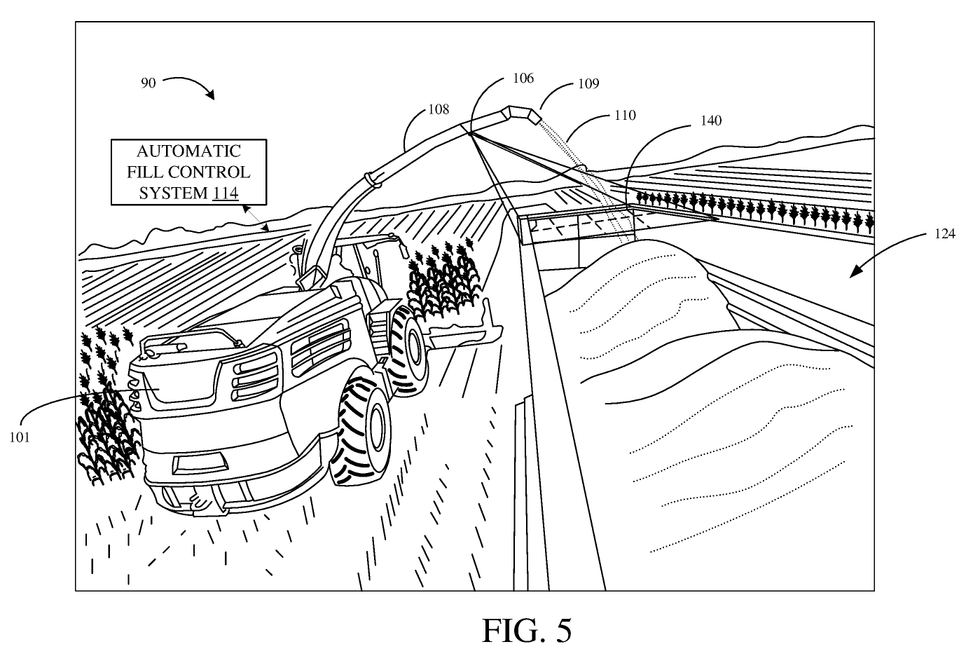

FIG. 5 is a pictorial illustration showing another example of unloading system 90 with self-propelled forage harvester 101, this time unloading material into a semi-trailer (or receiving vessel on a receiving vehicle) 124 in a configuration in which a semi-tractor (also referred to as a following vehicle) is pulling semi-trailer 124 alongside forage harvester 101.Therefore, the spout 108 and flap 109 are positioned to unload the harvested material 110 to fill trailer 124 according to a pre-defined side-by-side fill strategy. Again, FIG. 5 shows that a camera or another perception sensor 106 can capture an image (which can include a still image or video) of semi-trailer 124. In the example illustrated in FIG. 5, the field of view of camera or other perception sensor 106 is directed toward the receiving area of trailer 124 so that image processing can be performed to identify a landing point for the harvested material in trailer 124. Automatic fill control system 114 can divide the opening of the semi-trailer 124 into a grid 140 of cells or grid locations. A machine synchronization system can nudge the semi-trailer 124 forward or rearward relative to harvester 101 to accomplish a fill strategy.

As discussed above, when conditions are favorable for performing automatic fill control using images captured by perception sensor 106, then automatic fill control system 114 can detect fill characteristics corresponding to an automatic unload operation performed using perception sensor 106. Those fill characteristics can include the time and grid location where harvester 101 unloaded material into semi-trailer 124, the fill level at each grid location or cell, the overall topology of material in semi-trailer 124 and/or at each cell or grid location, among other things. Automatic fill control system 114 can also detect, estimate, or otherwise obtain a fill rate at which harvester 101 unloaded material into semi-trailer 124.

Automatic fill control system 114 can then simulate fill characteristics for each of a plurality of different trailer geometries and compare the simulated fill characteristics against the fill characteristics generated based on the output of perception sensor 106 to identify an error value corresponding to each of the plurality of different geometries. The geometry that has a lowest corresponding error value is then selected and can be used as the geometry of semi-trailer 124 during subsequent unloading operations into semi-trailer 124. Such subsequent unloading operations can then be automatically controlled using the simulator instead of using the perception sensor 106.

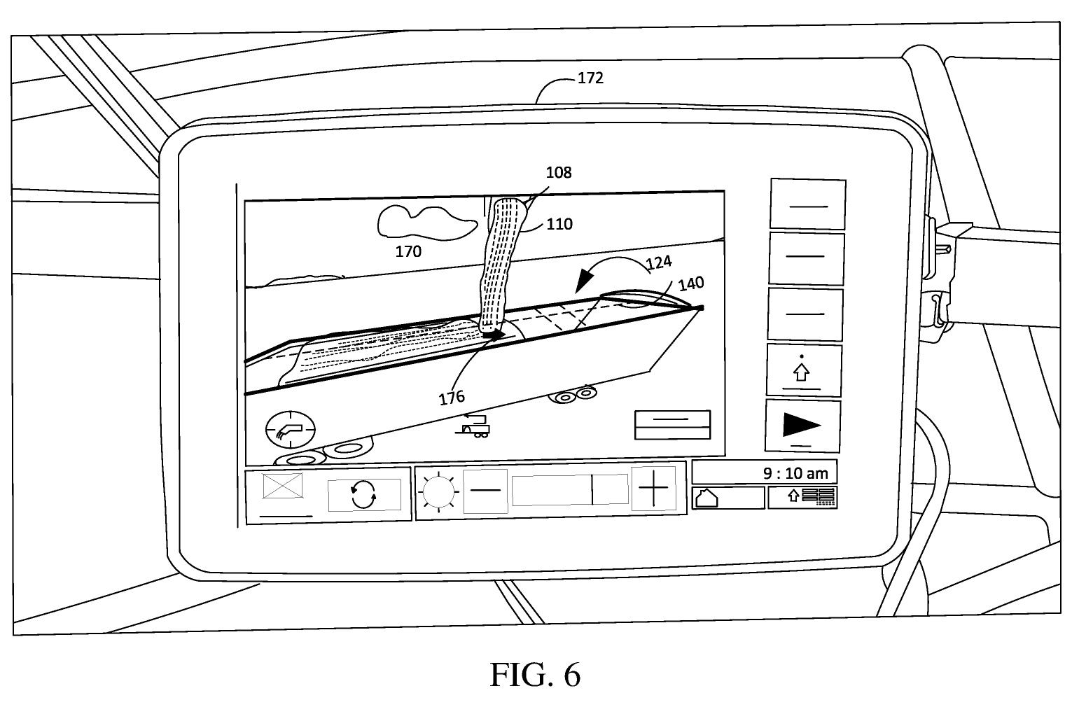

FIG. 6 is a pictorial illustration showing one example of an operator interface display 170 that can be displayed on a display mechanism 172, for the operator in an operator compartment of harvester 100, harvester 101, tractor 104, semi-truck 122, or on a display screen of a mobile device carried by the operator or in the operator compartment of various different vehicles, etc. The operator interface display 170 in FIG. 6 shows a view of images (static or video) captured by perception sensor 106. The image(s) show material 110 entering trailer 124. An image processing system in automatic fill control system 114 illustratively processes point cloud data in the image of the material 110 in trailer 124 to determine the fill height of material in semi-trailer 124.

Once the fill level of material in semi-trailer 124 is detected and/or calculated, the fill level of material in semi-trailer 124 can be compared to a threshold fill level. In one example, in which the harvester 100, 101 has an automatic fill control system 114 which controls an unloading operation to fill trailer 124 according to a fill strategy (such as a back-to-front fill strategy, front-to-back fill strategy, etc.), the fill control system 114 divides the opening of trailer 124 into a grid 140 of cells or grid locations. A current landing position indicator (such as indicator 176) may be displayed to show the current cell or grid location corresponding to the current landing position where material 110 is being loaded into trailer 124 through spout 108 and the direction that spout 108 is, or should be, moving relative to trailer 124 as the filling operation continues.

In one example, the same type of user interface display 170 can be generated using simulated fill characteristics, such as the simulated fill height, the simulated topography of material 110 in the cells or grid locations in trailer 124, etc. Thus, even when conditions are unfavorable for using perception sensor 106, display 170 can be generated using simulated fill characteristics instead of perceived fill characteristics.

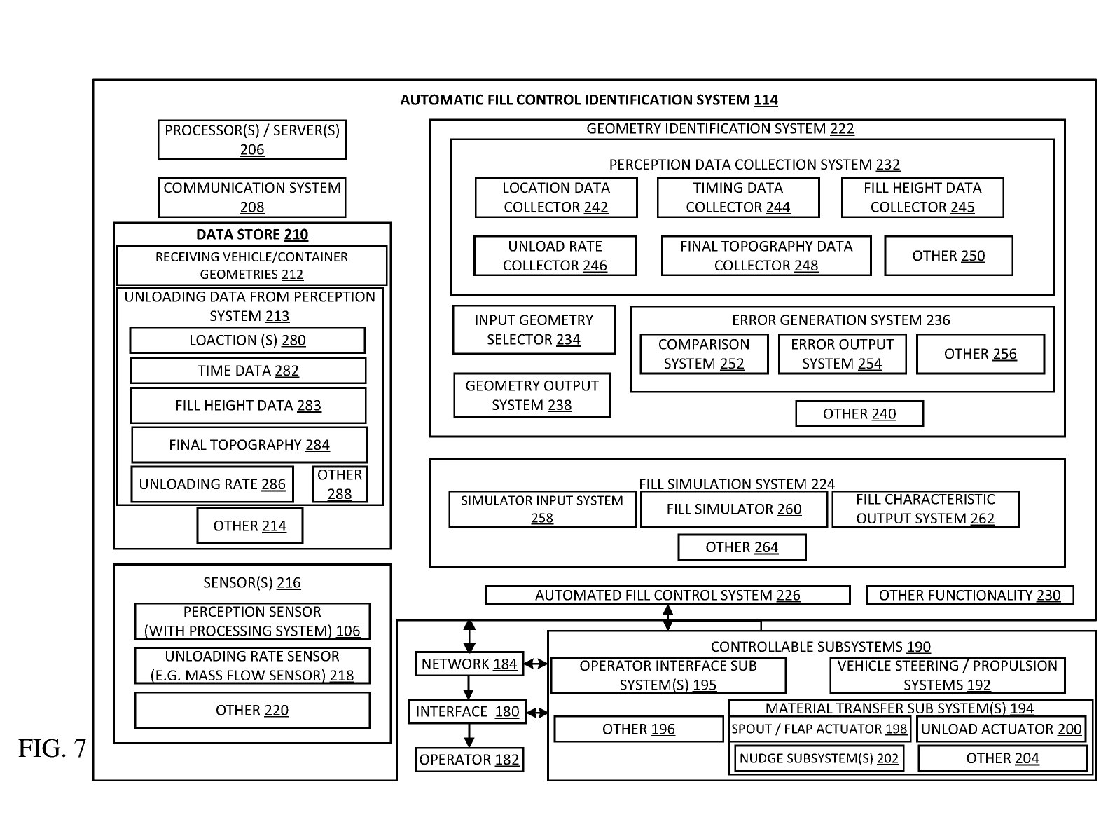

FIG. 7 is a block diagram showing one example of automatic fill control system 114 (or simply fill control system 114) in more detail. FIG. 7 shows that fill control system 114 can generate interfaces 180 for interaction by operator 182. Operator 182 can illustratively interact with interfaces 180 to control and manipulate portions of fill control system 114. In one example, fill control system 114 generates interfaces 180 over network 184. For instance, fill control system 114 can communicate over network 184 with a mobile device or other device to which operator 182 has access. Also, in one example, fill control system 114 can communicate with other machines 186 (e.g., other machines illustrated in FIGS. 1-5 above, or still other machines) and other systems 188. Other systems 188 may be farm manager systems, systems in remote server environments, or other systems.

FIG. 7 also shows that, in one example, fill control system 114 can communicate directly or over network 184 with other controllable subsystems 190. Other controllable subsystems 190 can include such things as vehicle steering and propulsion subsystem(s) 192 for one or both of the material unloading vehicle and the material receiving vehicle or container, material transfer subsystems 194, operator interface systems 195, and other subsystems 196. Steering and propulsion subsystem(s) 192 may be one or more internal combustion engines, electric motors, transmissions, individual drive motors, or other devices that can be used to generate propulsion of one or more of the vehicles referenced herein as well as steering components that can be actuated to change the heading of such vehicles

Material transfer subsystem(s) 194 control the transfer of material from the unloading vehicle to the receiving vehicle or container. Thus, material transfer subsystem(s) 194 can include spout/flap actuators 198 which control the position of the spouts and/or flaps on the unloading vehicle, unload actuators 200 which may be fans, augers, elevators, conveyors, or other actuators that are actuated to transfer material from the unloading vehicle to the receiving vehicle or container, nudge subsystem 202 that is used to change the relative position of the unloading vehicle relative to the material receiving vehicle or container, and/or any of a wide variety of other material transfer subsystems 204.

Operator interface subsystems 195 can be used to generate interfaces 180 or generate representations of those interfaces which may be communicated to another device for display on an interface 180. Operator interface subsystems 195 can also be located on any variety of different vehicles, devices, etc. Operator interface system 195 includes interface mechanisms that can be used by operator 182. Operator 182 me may be a manual operator, an automated operator, or a semi-automated operator. The operator interface mechanisms in operator interface system 195 can include a steering wheel, joysticks, levers, pedals, knobs, buttons, or other input mechanisms. Further, the interface mechanisms can include a display screen that displays information on interfaces 180 for operator 182 and may receive inputs from operator 182. For instance, a display may include actuatable elements such as icons, links, buttons, etc. The display screen may be a touch sensitive display screen, and the interface mechanisms may also include voice-related mechanisms, such as microphone, speaker, speech synthesis functionality, speech recognition functionality, among other things. Thus, the actuatable elements may be actuated by operator 182 using a point-and-click device, touch gestures, voice commands,

In one example, network 184 may be a wide area network, a local area network, a cellular communication network, a Wi-Fi or Bluetooth network, a near field communication network, or any of a variety of other networks or combinations of networks.

FIG. 7 also shows that fill control system 114 can include processors or servers 206, communication system 208, data store 210 (which can include receiving vehicle/container geometries 212, unloading data 213 from perception system 206, and other data 214), sensors 216 which can include perception sensor 106 (with a processing system, such as an image processing system or another processing system), an unloading rate sensor 218 (which can include such things as a mass flow rate sensor or another sensor that senses the rate at which material is being unloaded from an unloading vehicle into a receiving vehicle or container), and other sensors 220, geometry identification system 222, fill simulation system 224, fill control processing system 226, and other functionality 230. Geometry identification system 222 can include perception data collection system 232, input geometry selector 234, error generation system 236, geometry output system 238, and other items 240. Perception data collection system 232 can include location data collector 242, timing data collector 244, unload rate collector 246, final topography data collector 248, and other items 250. Error generation system 236 can include comparison system 252, error output system 254, and other items 256. Fill simulation system 224 can include simulator input system 258, fill simulator 260, fill characteristic output system 262, and other items 264. Before describing the operation of automatic fill control system 114 in more detail, a description of some of the items in automatic fill control system 114, and their operation, will first be provided.

Communication system 208 illustratively enables communication of the various items in fill control system 114 with respect to one another. Therefore, communication system 208 may be a controller area network (CAN) bus and bus controller. Communication system 208 can also facilitate communication over network 184, such as a cellular communication system, a near field communication system, a Bluetooth or Wi-Fi communication system, a wide area network communication system, a local area network communication system, and/or any of a variety of other communication systems or combinations of systems.

Receiving vehicle/container geometries 212 can include data defining the geometry of each of a plurality of different receiving vehicles or containers. Such geometry data can include a vehicle type indicator identifying an overall shape of the vehicle (such as double hopper bottom, single hopper bottom, grain cart, etc.), a side wall angle indicator identifying a side wall angle of the receiving vehicle or container (e.g., an angle value relative to horizontal), a front wall angle indicator identifying an angle of a front wall of the receiving vehicle or container (e.g., an angle relative to horizontal), and/or any of wide variety of other geometry data. It will be noted that receiving vehicle/container geometries 212 may be received by system 114 from an operator 182 through an interface 180, retrieved or downloaded from another system 188, or obtained or received in other ways.

Unloading data 213 that is generated based on outputs from perception sensor 106 can include fill characteristics for the unloading operation, such as locations 280, time data 282, fill height data 283, final topography data 284, unloading rate data 286, and other unloading data or fill characteristics 288. Location data 280 can identify the grid section or cell location where the exit end of spout 108 was located to load material into the receiving vehicle or container. Time data 282 can indicate the time during which the spout 108 was located at an identified location 280. Time data 282 can thus include timestamp data indicating a time when the outlet end of spout 108 is positioned over a grid location and timestamp data indicating when the outlet end of spout 108 was moved to a different grid location. Fill height data 283 can identify the fill height of material loaded into each cell or grid location. Final topography data 284 can identify the final overall topography of material in the receiving vehicle or container, and/or in each cell or grid location. Unloading rate data 286 can identify the rate at which material was being unloaded by the unloading vehicle into the receiving vehicle or container. The unloading rate data 286 can have different granularity. Unloading rate data 286 may identify an overall average unloading rate at which material was unloaded, the average unloading rate at which material was loaded into each cell or grid location, or more or less fine granularity.

Perception sensor 106 can include a mono or stereo camera that captures a static image or video, a LIDAR sensor, RADAR sensor, or another sensor that that is configured to capture three-dimensional (3D) data corresponding to the receiving vehicle or container that is to be, or that is being, loaded.

Unloading rate sensor 218 may be of mass flow rate sensor positioned in spout 108, at the outlet end of spout 108, or elsewhere on the harvester unloaded by the harvester into the receiving vehicle or container. In another example, unloading rate sensor 218 may be a scale parent e.g., load cells in the axles of a grain cart) that measure the change in weight of the grain cart over time as the grain cart is being loaded with material by a harvester. That change in weight over time can be used to identify the average unloading rate for the material that is being transferred into the receiving vehicle or container. The unloading rate sensor 218 can be a system that estimates the unloading rate or measures the unloading rate in other ways.

Geometry identification system 222 collects data and generates an output indicative of a geometry corresponding to a receiving vehicle or container. Perception data collection system 232 collects data generated based upon the output of perception sensor 106 during an unloading operation. Thus, location data collector 242 can collect the location data 280 corresponding to an unloading operation. Timing data collector 244 can collect the time data 282 corresponding to that unloading operation. Fill height data collector 245 can collect fill height data 283 corresponding to the unloading operation. Final topography data collector 248 can collect the final topography data 284 corresponding to the unloading operation, and unloading rate collector 246 may collect the unloading rate data 286 corresponding to the unloading operation. It will be noted that perception data collection system 232 can collect other fill characteristics corresponding to the unloading operation as well.

Input geometry selector 234 then selects one of the receiving vehicle/container geometries 212 for simulation. That selected geometry 212 is provided, along with the unloading rate data 286, to fill simulation system 224 so that fill simulation system 224 can generate simulated fill characteristics using fill simulator 260. Simulator input system 258 obtains those inputs (the unloading rate data 286 and the selected receiving vehicle/container geometry 212) and provides them to fill simulator 260. Fill simulator 260 may be an algorithm that simulates the piling behavior of material as the material is loaded at a particular unloading rate 286 into a receiving vehicle or container. Fill simulator 260 takes the geometry of the receiving vehicle or container and the unloading rate and performs a simulation indicating how the material being unloaded piles into the receiving vehicle or container having the identified geometry 212.

Thus, fill simulator 260 can be used to simulate the fill height or topography of material in each cell or grid location of a receiving vehicle or container, given the unloading rate at that location. When the simulated fill height reaches a threshold fill height, then fill characteristic output system 262 can generate an output indicating that the position of the spout 108 should be changed to a different cell or grid location. Once spout 108 is relocated, fill simulator 260 then begins simulating the fill height or topography of material at the new cell or grid location. When that fill height or topography reaches a desired level, then fill characteristic output system 262 can generate an output indicating that the location of the spout should again be changed. This continues until fill simulator 260 indicates that the overall fill height in the final cell or grid location, and/or the overall fill height in the receiving vehicle or container, has reached a desired level. At that point, it will be noted that fill characteristic output system 262 will have generated and output simulated values for fill characteristics, such as location data, timing data, fill height data, and final topography data. The simulated values may be similar to the location data 280, time data 282, fill height data 283, and final topography data 284 that were generated using perception sensor 106.

Error generation system 236 can then generate an error between the simulated fill characteristics output by fill characteristic output system 262 for the selected geometry and the fill characteristics output by perception data collection system 232. Comparison system 252 compares the simulated fill characteristics against the fill characteristics generated using perception sensor 106. Error output system 254 outputs one or more values indicative of an error between the simulated fill characteristics and those generated using perception sensor 106.

Fill simulation system 224 can perform a plurality of different simulations using a plurality of different receiving vehicle/container geometries 212, and error generation system 236 can generate an error value for each of those geometries. Geometry output system 238 can select the geometry based on the corresponding error value as the geometry corresponding to the receiving vehicle/container under analysis. In one example, geometry output system 238 outputs, as the identified geometry, a geometry that has an error value that is less than a threshold value. In another example, geometry output system 238 outputs, as the identified geometry, the geometry that has the lowest corresponding error value. Further, it will be noted that input geometry selector 234 can select all receiving vehicle/container geometries 212, that are available, for simulation. In another example, input geometry selector 234 can select the top N most likely geometries for simulation, the top N most widely used geometries, etc.

Fill control processing system 226 can generate control signals to control the controllable subsystems 190 to perform an unloading operation according to a desired fill pattern, or in other ways, based upon the fill characteristics generated using perception sensor 106 or based on simulated fill characteristics generated using fill simulation system 224. Thus, fill control processing system 226 can generate control signals to generate operator interfaces 180, to control the steering and propulsion subsystems 192, to control material transfer subsystem 194, or to perform other control operations to generate other control signals to control the unloading operation as desired, based upon perceived or simulated fill characteristics.

Therefore, when conditions are favorable for using perception sensor 106, fill control processing system 226 can perform automated fill control based on fill characteristics sensed from perception sensor 106. However, when conditions are unfavorable for using perception sensor 106, then fill control processing system 226 can perform automated fill control based on outputs from fill simulation system 224.

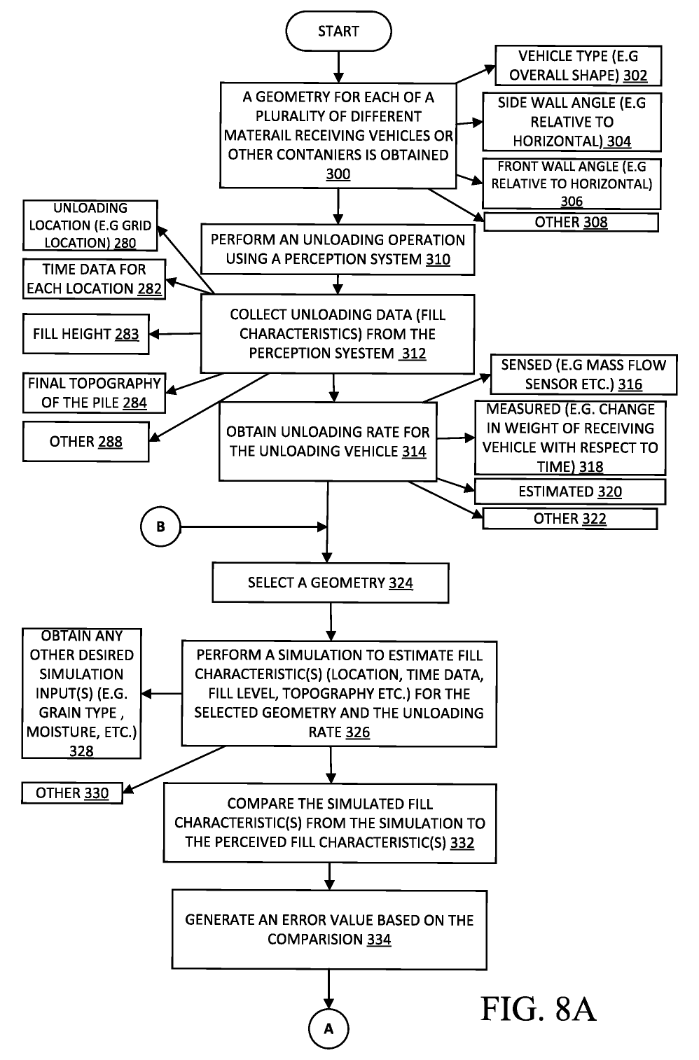

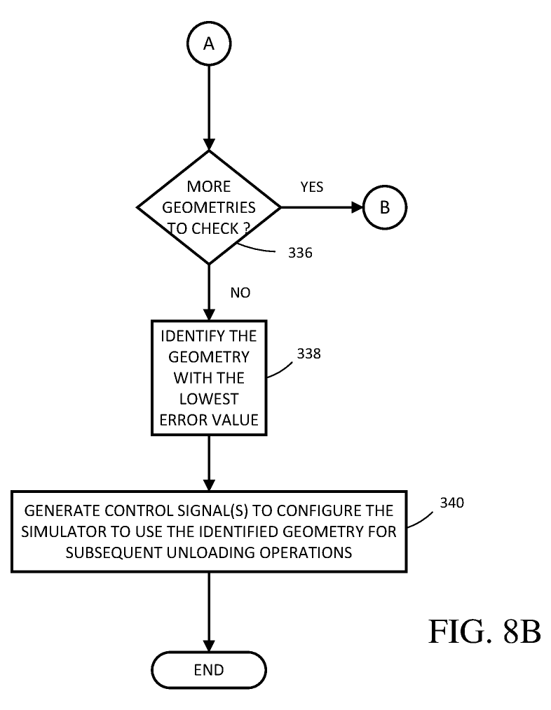

FIGS. 8A and 8B (collectively referred to herein as FIG. 8) show a flow diagram illustrating one example of the operation of automatic fill control system 114 in identifying a receiving vehicle or container geometry that can be used by fill simulation system 224 to simulate fill characteristics that are used during automated unloading. It is first assumed that a plurality of receiving vehicle/container geometries 212 for different material receiving vehicles or other containers are obtained, as indicated by block 300 in the flow diagram of FIG. 8. Geometries 212 can include such things as vehicle type (e.g., overall shape) 302, sidewall angle (e.g., the angle of the side walls relative to horizontal) 304, front wall angle (e.g., the angle of the front wall relative to horizontal) 306, and any of a wide variety of other geometry data 308.

When conditions are favorable for performing an unloading operation and controlling that operation based on outputs from perception sensor 106, then an unloading operation is performed, using perception sensor 106, as indicated. Such conditions may include high light conditions, low dust conditions, etc. Performing such an unloading operation is indicated by block 310 in the flow diagram of FIG. 8.

Perception data collection system 232 then collects fill characteristic data based upon outputs from perception sensor 106, as indicated by block 312 in the flow diagram of FIG. 8. For instance, location data collector 242 can collect the locations 280 (e.g. the grid locations or cell locations) where material was unloaded. Time data collector 244 can collect time data indicating the time that material was loaded into each of the locations 280. Fill height data collector 245 can collect fill height data 283 that identifies the height of material loaded at each location 280, and/or the overall height of material loaded into the receiving vehicle or container. Final topography data collector 248 can collect final topography data 284 which identifies the final topography of material loaded at each location 280 and/or the final topography of the material loaded into the receiving vehicle or container.

Unload rate collector 246 can obtain the unloading rate at which the unloading vehicle unloaded material into the receiving vehicle or container, as indicated by block 314 in the flow diagram of FIG. 8. As mentioned above, the unloading rate can be sensed by a loading rate sensor 218, as indicated by block 316 and the flow diagram of FIG. 8. The unloading rate can be measured (such as by measuring the change in weight of the receiving vehicle with respect to time) as indicated by block 318, and/or the unloading rate can be estimated 320 or identified or calculated in other ways 322.

Geometry identification system 222 can then begin automatically identifying which of the receiving vehicle/container geometries 212 best matches the geometry of the receiving vehicle or container just loaded with material. Thus, input geometry selector 234 selects one of the receiving vehicle/container geometries 212 for analysis. Selecting a geometry as indicated by block 324 in the flow diagram of FIG. 8.

Fill simulation system 224 then performs a simulation to estimate fill characteristics (e.g., location and time data, fill level, topography, etc.) for the selected geometry, given the unloading rate, as indicated by block 326. To perform the simulation, simulator input system 258 can obtain the selected geometry as well as any other inputs, such as the unloading rate, grain type, grain moisture, or other values or inputs that may affect the simulation. Obtaining such inputs is indicated by block 328 in the flow diagram of FIG. 8. Based upon the inputs, fill simulator 260 can perform a simulation simulating how the material piles in the receiving vehicle/container having the selected geometry 212. Fill characteristic output system 262 outputs the simulated fill characteristics generated by fill simulator 260 for use by geometry identification system 222. Fill simulation system 224 can perform the simulation in other ways as well, as indicated by block 330.

Error generation system 236 then generates an error value corresponding to the receiving vehicle/container geometry under analysis. Thus, comparison system 252 compares the simulated fill characteristic values output by fill characteristic output system 262 to the fill characteristic values generated using perception sensor 106 and collected by perception data collection system 232. Comparing the simulated fill characteristic values to the perceived fill characteristic values is indicated by block 332 in the flow diagram of FIG. 8. Error output system 254 then generates an error value corresponding to the selected receiving vehicle/container geometry 212 based upon the difference between the simulated fill characteristic values and the perceived fill characteristic values. Generating an error value based upon the comparison is indicated by block 334 in the flow diagram of FIG. 8.

If there are more receiving vehicle/container geometries 212 to check, as determined at block 336, then processing reverts to block 324 where the next receiving vehicle/container geometry 212 to be analyzed is selected by input geometry selector 234.

Once of all the receiving vehicle/container geometries 212 have been analyzed, or once a desired subset of geometries 212 has been analyzed, geometry output system 238 identifies the receiving vehicle/container geometry 212 that has the lowest corresponding error value, as indicated by block 338 in the flow diagram of FIG. 8. Geometry output system 238 then provides the identified geometry to fill simulation system 224 which is then configured to use that geometry to simulate fill characteristics during subsequent unloading operations into the receiving vehicle or container. Configuring the fill simulator 262 use the identified geometry for subsequent unloading operations as indicated by block 340 in the flow diagram of FIG. 8.

It can thus be seen that the present description describes a system that can automatically identify the geometry of a receiving vehicle or container so that geometry can be used by a simulator to generate simulated fill characteristics that are used in automated fill control (e.g., controlling an automatic unloading operation to unload material from an unloading vehicle into a receiving vehicle or container). When conditions are favorable, and unloading operation is performed based on inputs from perception sensor 106, and fill characteristics characterizing that unloading operation are detected or computed and stored. Then, a simulator simulates a different set of fill characteristic values for each of a plurality of different possible receiving vehicle/container geometries. The simulated fill characteristic values are compared against the perceived fill characteristic values, for each geometry, to identify a corresponding error value. The geometry with the lowest corresponding error value is identified as the likely geometry of the receiving vehicle/container. That geometry can then be used to control automated unloading based upon simulated fill characteristics that are generated by the simulator. This enables accurate automatic control of unloading operations, even under circumstances which are unfavorable for using a perception sensor.

The present discussion has mentioned processors and servers. In one example, the processors and servers include computer processors with associated memory and timing circuitry, not separately shown. The processors or servers are functional parts of the systems or devices to which they belong and are activated by, and facilitate the functionality of the other components or items in those systems.

Also, a number of user interface (UI) displays have been discussed. The UI displays can take a wide variety of different forms and can have a wide variety of different user actuatable input mechanisms disposed thereon. For instance, the user actuatable input mechanisms can be text boxes, check boxes, icons, links, drop-down menus, search boxes, etc. The mechanisms can also be actuated in a wide variety of different ways. For instance, the mechanisms can be actuated using a point and click device (such as a track ball or mouse). The mechanisms can be actuated using hardware buttons, switches, a joystick or keyboard, thumb switches or thumb pads, etc. The mechanisms can also be actuated using a virtual keyboard or other virtual actuators. In addition, where the screen on which the mechanisms are displayed is a touch sensitive screen, the mechanisms can be actuated using touch gestures. Also, where the device that displays the mechanisms has speech recognition components, the mechanisms can be actuated using speech commands.

A number of data stores have also been discussed. It will be noted the data stores can each be broken into multiple data stores. All can be local to the systems accessing the data stores, all can be remote, or some can be local while others are remote. All of these configurations are contemplated herein.

Also, the figures show a number of blocks with functionality ascribed to each block. It will be noted that fewer blocks can be used so the functionality is performed by fewer components. Also, more blocks can be used with the functionality distributed among more components.

It will be noted that the above discussion has described a variety of different systems, components, generators, selectors, simulators, and/or logic. It will be appreciated that such systems, components, generators, selectors, simulators, and/or logic can be comprised of hardware items (such as processors and associated memory, or other processing components, some of which are described below) that perform the functions associated with those systems, components, generators, selectors, simulators, and/or logic. In addition, the systems, components, generators, selectors, simulators, and/or logic can be comprised of software that is loaded into a memory and is subsequently executed by a processor or server, or other computing component, as described below. The systems, components, generators, selectors, simulators, and/or logic can also be comprised of different combinations of hardware, software, firmware, etc., some examples of which are described below. These are only some examples of different structures that can be used to form the systems, components, generators, selectors, simulators, and/or logic described above. Other structures can be used as well.

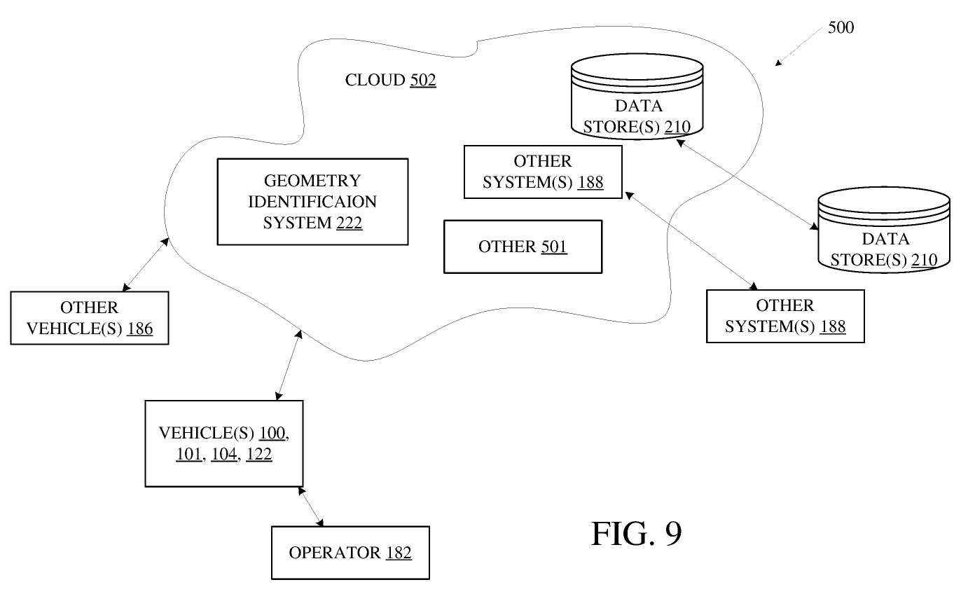

FIG. 9 is a block diagram of system 90, shown in other FIGs., except that system 90 is disposed in a remote server architecture 500. In an example, remote server architecture 500 can provide computation, software, data access, and storage services that do not require end-user knowledge of the physical location or configuration of the system that delivers the services. In various examples, remote servers can deliver the services over a wide area network, such as the internet, using appropriate protocols. For instance, remote servers can deliver applications over a wide area network and they can be accessed through a web browser or any other computing component. Software or components shown in previous FIGS. as well as the corresponding data, can be stored on servers at a remote location. The computing resources in a remote server environment can be consolidated at a remote data center location or they can be dispersed. Remote server infrastructures can deliver services through shared data centers, even though they appear as a single point of access for the user. Thus, the components and functions described herein can be provided from a remote server at a remote location using a remote server architecture. Alternatively, the components and functions can be provided from a conventional server, or they can be installed on client devices directly, or in other ways.

In the example shown in FIG. 9, some items are similar to those shown in previous FIGS. and they are similarly numbered. FIG. 9 specifically shows that geometry identification system 222, other systems 188, data store 210, and/or other items 501 can be located at a remote server location 502. Therefore, vehicles 100, 101,104, 122, 186 access those systems through remote server location 502.

FIG. 9 also depicts another example of remote server architecture. FIG. 9 shows that it is also contemplated that some elements of previous FIGS are disposed at remote server location 502 while others are not. By way of example, data store 210 and/or other systems 188 can be disposed at a location separate from location 502 and accessed through the remote server at location 502. Regardless of where the items are located, the items can be accessed directly by the vehicles, through a network (either a wide area network or a local area network), the items can be hosted at a remote site by a service, or the items can be provided as a service, or accessed by a connection service that resides in a remote location. Also, the data can be stored in substantially any location and intermittently accessed by, or forwarded to, interested parties. All of these architectures are contemplated herein.

It will also be noted that the elements of previous FIGS., or portions of them, can be disposed on a wide variety of different devices. Some of those devices include servers, desktop computers, laptop computers, tablet computers, or other mobile devices, such as palm top computers, cell phones, smart phones, multimedia players, personal digital assistants, etc.

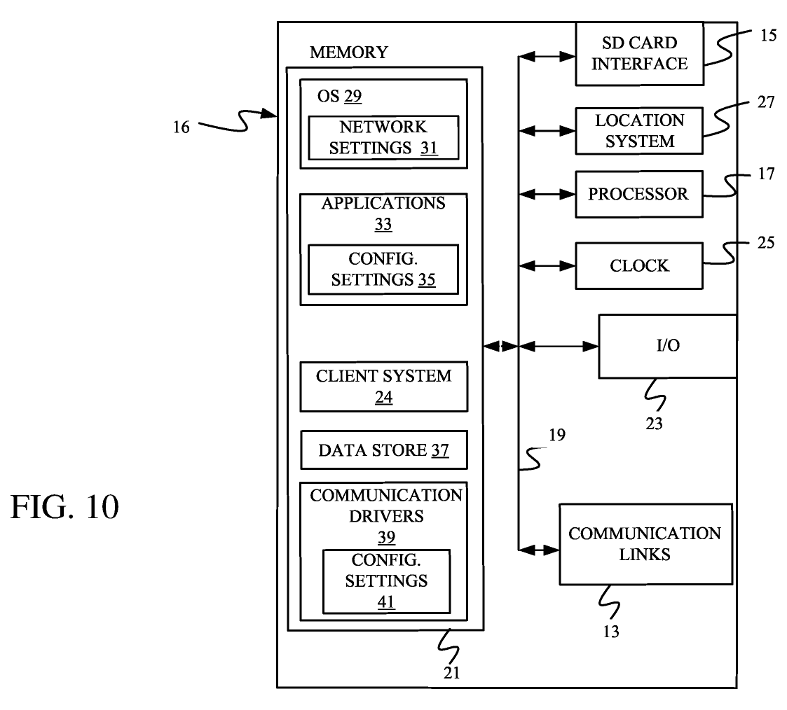

FIG. 10 is a simplified block diagram of one illustrative example of a handheld or mobile computing device that can be used as a user’s or client’s handheld device 16, in which the present system (or parts of it) can be deployed. For instance, a mobile device can be deployed in the operator compartment of one or more vehicles 100, 101, 104, 122, 186 for use in generating, processing, or displaying the geometry and fill characteristic data. FIGS. 10-12 are examples of handheld or mobile devices.

FIG. 10 provides a general block diagram of the components of a client device 16 that can run some components shown in previous FIGS., that interacts with them, or both. In the device 16, a communications link 13 is provided that allows the handheld device to communicate with other computing devices and under some examples provides a channel for receiving information automatically, such as by scanning. Examples of communications link 13 include allowing communication though one or more communication protocols, such as wireless services used to provide cellular access to a network, as well as protocols that provide local wireless connections to networks.

In other examples, applications can be received on a removable Secure Digital (SD) card that is connected to an interface 15. Interface 15 and communication links 13 communicate with a processor 17 (which can also embody processors or servers from previous FIGS.) along a bus 19 that is also connected to memory 21 and input/output (I/O) components 23, as well as clock 25 and location system 27.

I/O components 23, in one example, are provided to facilitate input and output operations. I/O components 23 for various examples of the device 16 can include input components such as buttons, touch sensors, optical sensors, microphones, touch screens, proximity sensors, accelerometers, orientation sensors and output components such as a display device, a speaker, and or a printer port. Other I/O components 23 can be used as well.

Clock 25 illustratively comprises a real time clock component that outputs a time and date. It can also, illustratively, provide timing functions for processor 17.

Location system 27 illustratively includes a component that outputs a current geographical location of device 16. This can include, for instance, a global positioning system (GPS) receiver, a dead reckoning system, a cellular triangulation system, or other positioning system. Location system 27 can also include, for example, mapping software or navigation software that generates desired maps, navigation routes and other geographic functions.

Memory 21 stores operating system 29, network settings 31, applications 33, application configuration settings 35, data store 37, communication drivers 39, and communication configuration settings 41. Memory 21 can include all types of tangible volatile and non-volatile computer-readable memory devices. Memory 21 can also include computer storage media (described below). Memory 21 stores computer readable instructions that, when executed by processor 17, cause the processor to perform computer-implemented steps or functions according to the instructions. Processor 17 can be activated by other components to facilitate their functionality as well.

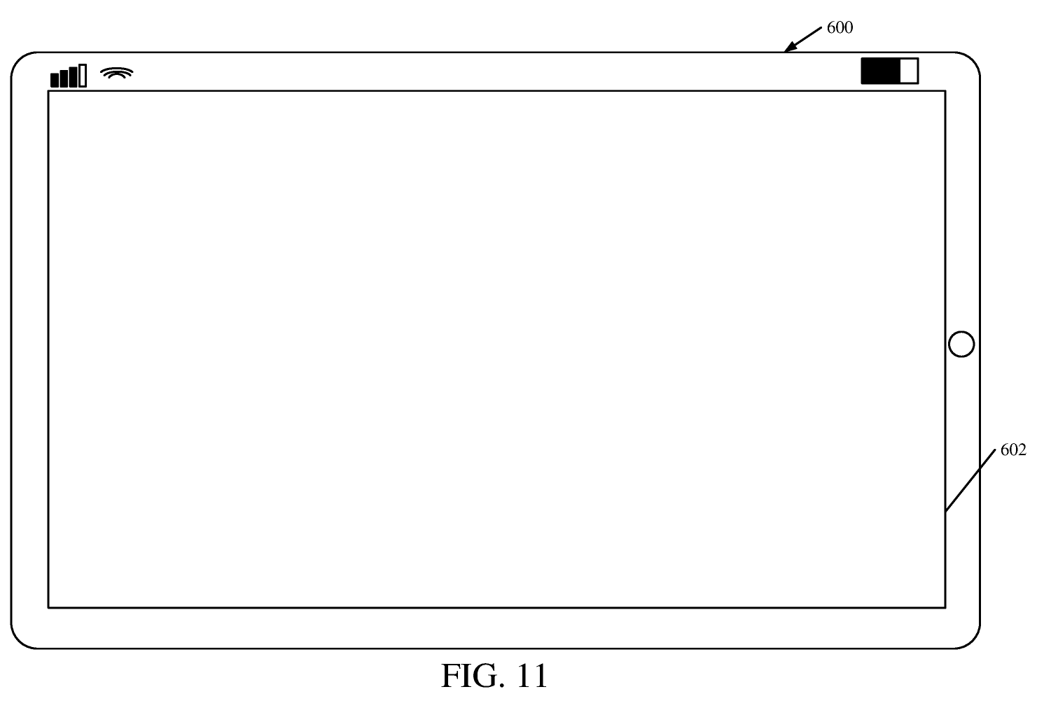

FIG. 11 shows one example in which device 16 is a tablet computer 600. In FIG. 11, computer 600 is shown with user interface display screen 602. Screen 602 can be a touch screen or a pen-enabled interface that receives inputs from a pen or stylus. Computer 600 can also use an on-screen virtual keyboard. Of course, computer 600 might also be attached to a keyboard or other user input device through a suitable attachment mechanism, such as a wireless link or USB port, for instance. Computer 600 can also illustratively receive voice inputs as well.

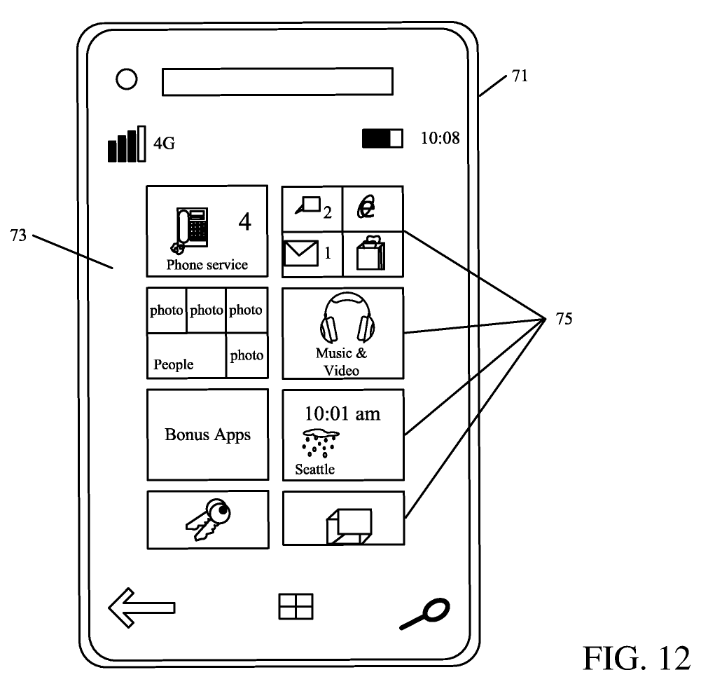

FIG. 12 shows that the device can be a smart phone 71. Smart phone 71 has a touch sensitive display 73 that displays icons or tiles or other user input mechanisms 75. Mechanisms 75 can be used by a user to run applications, make calls, perform data transfer operations, etc. In general, smart phone 71 is built on a mobile operating system and offers more advanced computing capability and connectivity than a feature phone.

Note that other forms of the devices 16 are possible.

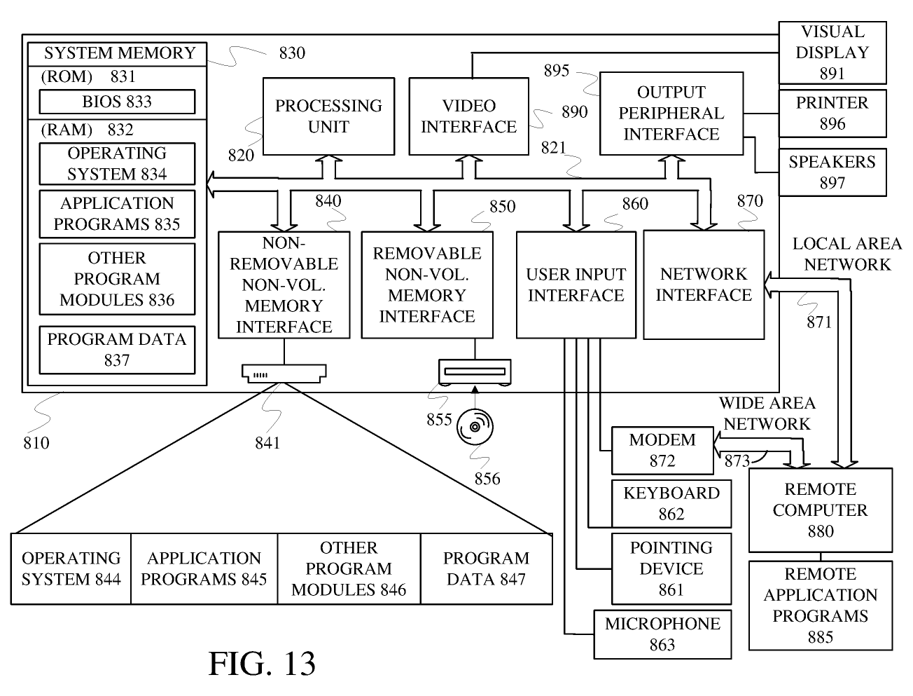

FIG. 13 is one example of a computing environment in which elements of previous FIGS., or parts of it, (for example) can be deployed. With reference to FIG. 13, an example system for implementing some embodiments includes a computing device in the form of a computer 810 programmed to operate as described above. Components of computer 810 may include, but are not limited to, a processing unit 820 (which can comprise processors or servers from previous FIGS.), a system memory 830, and a system bus 821 that couples various system components including the system memory to the processing unit 820. The system bus 821 may be any of several types of bus structures including a memory bus or memory controller, a peripheral bus, and a local bus using any of a variety of bus architectures. Memory and programs described with respect to previous FIGS. can be deployed in corresponding portions of FIG. 13.

Computer 810 typically includes a variety of computer readable media. Computer readable media can be any available media that can be accessed by computer 810 and includes both volatile and nonvolatile media, removable and non-removable media. By way of example, and not limitation, computer readable media may comprise computer storage media and communication media. Computer storage media is different from, and does not include, a modulated data signal or carrier wave. Computer storage media includes hardware storage media including both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computer 810. Communication media may embody computer readable instructions, data structures, program modules or other data in a transport mechanism and includes any information delivery media. The term “modulated data signal” means a signal that has one or more of its characteristics set or changed in such a manner as to encode information in the signal.

The system memory 830 includes computer storage media in the form of volatile and/or nonvolatile memory such as read only memory (ROM) 831 and random access memory (RAM) 832. A basic input/output system 833 (BIOS), containing the basic routines that help to transfer information between elements within computer 810, such as during start-up, is typically stored in ROM 831. RAM 832 typically contains data and/or program modules that are immediately accessible to and/or presently being operated on by processing unit 820. By way of example, and not limitation, FIG. 13 illustrates operating system 834, application programs 835, other program modules 836, and program data 837.

The computer 810 may also include other removable/non-removable volatile/nonvolatile computer storage media. By way of example only, FIG. 13 illustrates a hard disk drive 841 that reads from or writes to non-removable, nonvolatile magnetic media, an optical disk drive 855, and nonvolatile optical disk 856. The hard disk drive 841 is typically connected to the system bus 821 through a non-removable memory interface such as interface 840, and optical disk drive 855 are typically connected to the system bus 821 by a removable memory interface, such as interface 850.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (e.g., ASICs), Application-specific Standard Products (e.g., ASSPs), System-on-a-chip systems (SOCs), Complex Programmable Logic Devices (CPLDs), etc.

The drives and their associated computer storage media discussed above and illustrated in FIG. 13, provide storage of computer readable instructions, data structures, program modules and other data for the computer 810. In FIG. 13, for example, hard disk drive 841 is illustrated as storing operating system 844, application programs 845, other program modules 846, and program data 847. Note that these components can either be the same as or different from operating system 834, application programs 835, other program modules 836, and program data 837.

A user may enter commands and information into the computer 810 through input devices such as a keyboard 862, a microphone 863, and a pointing device 861, such as a mouse, trackball or touch pad. Other input devices (not shown) may include a joystick, game pad, satellite dish, scanner, or the like. These and other input devices are often connected to the processing unit 820 through a user input interface 860 that is coupled to the system bus, but may be connected by other interface and bus structures. A visual display 891 or other type of display device is also connected to the system bus 821 via an interface, such as a video interface 890. In addition to the monitor, computers may also include other peripheral output devices such as speakers 897 and printer 896, which may be connected through an output peripheral interface 895.

The computer 810 is operated in a networked environment using logical connections (such as a controller area network – CAN, local area network - LAN, or wide area network WAN) to one or more remote computers, such as a remote computer 880.

When used in a LAN networking environment, the computer 810 is connected to the LAN 871 through a network interface or adapter 870. When used in a WAN networking environment, the computer 810 typically includes a modem 872 or other means for establishing communications over the WAN 873, such as the Internet. In a networked environment, program modules may be stored in a remote memory storage device. FIG. 13 illustrates, for example, that remote application programs 885 can reside on remote computer 880.

It should also be noted that the different examples described herein can be combined in different ways. That is, parts of one or more examples can be combined with parts of one or more other examples. All of this is contemplated herein.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A computer implemented method, comprising:
accessing a set of perception-based fill characteristics corresponding to an unloading operation in which an unloading vehicle unloaded material into a container, the perception-based fill characteristics being generated based on an output from a perception sensor;
selecting a container geometry of a plurality of container geometries;
performing a simulation with a simulator to generate a set of simulated fill characteristics for the selected container geometry;
repeating steps of selecting a container geometry and performing a simulation, to obtain a plurality of sets of simulated fill characteristics, each set of simulated fill characteristics corresponding to a different container geometry of the plurality of container geometries; and
identifying, as an identified container geometry, one of the plurality of container geometries based on the set of simulated fill characteristics corresponding to the identified container geometry and based on the set of perception-based fill characteristics.

2. The computer implemented method of claim 1 and further comprising:
generating a control signal to configure the simulator to generate simulated fill characteristics for the identified container geometry during a subsequent unloading operation.

3. The computer implemented method of claim 1 wherein identifying, as an identified container geometry, one of the plurality of container geometries, comprises:
comparing each set of simulated fill characteristics to the perception-based fill characteristics to obtain a comparison result corresponding to each set of simulated fill characteristics.

4. The computer implemented method of claim 3 wherein identifying, as an identified container geometry, one of the plurality of container geometries, comprises:
generating an error value corresponding to each of the plurality of container geometries based on the comparison result corresponding to each set of simulated fill characteristics; and
identifying the one of the plurality of container geometries as the identified container geometry based on the error value corresponding to each of the plurality of container geometries.

5. The computer implemented method of claim 4
wherein identifying the one of the plurality of container geometries as the identified container geometry based on the error value corresponding to each of the plurality of container geometries comprises:
identifying the one of the plurality of container geometries as the container geometry having the lowest corresponding error value.

6. The computer implemented method of claim 4
wherein identifying the one of the plurality of container geometries as the identified container geometry based on the error value corresponding to each of the plurality of container geometries comprises:
identifying the one of the plurality of container geometries as a container geometry having a corresponding error value that meets an error value threshold.

7. The computer implemented method of claim 1
wherein performing a simulation with a simulator to generate a set of simulated fill characteristics for the selected container geometry comprises:
identifying an unloading rate at which the unloading vehicle unloaded the material into the container during the unloading operation; and
generating a simulated fill height indicative of a simulated height of the material in the container based on the selected container geometry and the unloading rate.

8. The computer implemented method of claim 7 wherein generating a simulated fill height comprises:
generating a separate simulated fill height value corresponding to each of a plurality of different locations in the container, each simulated fill height value being indicative of a simulated height of the material at the corresponding location in the container.

9. The computer implemented method of claim 1
wherein performing a simulation with a simulator to generate a set of simulated fill characteristics for the selected container geometry comprises:
identifying an unloading rate at which the unloading vehicle unloaded the material into the container during the unloading operation; and
generating a simulated topography indicative of a simulated topology of the material in the container based on the selected container geometry and the unloading rate.

10. The computer implemented method of claim 9 wherein generating a simulated topography comprises:
generating a separate simulated topography corresponding to each of a plurality of different locations in the container, each simulated topography being indicative of a simulated topology of the material at the corresponding location in the container.

11. An unloading system, comprising:
a perception data collection system configured to access a set of perception-based fill characteristics corresponding to an unloading operation in which an unloading vehicle unloaded material into a container, the perception-based fill characteristics being generated based on an output from a perception sensor;
an input geometry selector configured to select a container geometry of a plurality of different container geometries;
a fill simulation system configured to perform a simulation to generate a set of simulated fill characteristics for the selected container geometry, the input geometry selector and the fill simulation system being configured to repeat selecting a container geometry and performing a simulation, to obtain a plurality of sets of simulated fill characteristics, each set of simulated fill characteristics corresponding to a different container geometry of the plurality of container geometries; and
a geometry identification system configured to identify, as a likely container geometry, one of the plurality of container geometries based on the set of simulated fill characteristics corresponding to the likely container geometry and based on the set of perception-based fill characteristics.

12. The unloading system of claim 11 and further comprising:
a geometry output system configured to generate a control signal to configure the simulator to generate simulated fill characteristics for the likely container geometry during a subsequent unloading operation.

13. The unloading system of claim 11 wherein the geometry identification system comprises:
a comparison system configured to compare each set of simulated fill characteristics to the perception-based fill characteristics to obtain a comparison result corresponding to each set of simulated fill characteristics.

14. The unloading system of claim 13 wherein the geometry identification system comprises:
an error output system configured to generate an error value corresponding to each of the plurality of container geometries based on the comparison result corresponding to each set of simulated fill characteristics; and
a geometry output system configured to identify the one of the plurality of container geometries as the likely container geometry based on the error value corresponding to each of the plurality of container geometries.

15. The unloading system of claim 14 wherein the geometry output system is configured to identify, as the likely container geometry, the container geometry having the lowest corresponding error value.

16. The unloading system of claim 11 wherein the fill simulation system comprises:
a simulator input system configured to identify an unloading rate at which the unloading vehicle unloaded the material into the container during the unloading operation; and
a fill simulator configured to generate a simulated fill height indicative of a simulated height of the material
in the container based on the selected container geometry and the unloading rate.

17. The unloading system of claim 16 wherein the fill simulator is configured to generate, as the simulated fill height, a separate simulated fill height value corresponding to each of a plurality of different locations in the container, each simulated fill height value being indicative of a simulated height of the material at the corresponding location in the container.

18. The unloading system of claim 11 wherein the fill simulation system comprises:
a simulator input system configured to identify an unloading rate at which the unloading vehicle unloaded the material into the container during the unloading operation; and
a fill simulator configured to generate a simulated topography indicative of a simulated topology of the material in the container based on the selected container geometry and the unloading rate.

19. The unloading system of claim 18 wherein the fill simulator is configured to generate, as the simulated topography, a separate simulated topography corresponding to each of a plurality of different locations in the container, each simulated topography being indicative of a simulated topology of the material at the corresponding location in the container.

20. A control system, comprising:
at least one processor;
a perception sensor configured to generate a set of perception-based fill characteristics corresponding to an unloading operation in which an unloading vehicle unloaded material into a container, the perception-based fill characteristics being generated based on an output from a perception sensor
an input geometry selector configured to select a container geometry of a plurality of different container geometries;
a fill simulation system configured generate a set of simulated fill characteristics for the selected container geometry, the input geometry selector and the fill simulation system being configured to repeat selecting a container geometry and performing a simulation, to obtain a plurality of sets of simulated fill characteristics, each set of simulated fill characteristics corresponding to a different container geometry of the plurality of container geometries; and
a geometry identification system, implemented by the at least one processor, configured to identify, as a likely container geometry, one of the plurality of container geometries based on the set of simulated fill characteristics corresponding to the likely container geometry and based on the set of perception-based fill characteristics.
